(19) United States
(12) Patent Application Publication
(10) Pub. No.: US 2011/0253195 A1
(43) Pub. Date: Oct. 20, 2011

(54) TORQUE TUBE SUPPORTER AND SOLAR TRACKER USING THE SAME

(75) Inventor: Scott W. Kim, Seoul (KR)

(73) Assignee: YOUIL ENSYS CO., LTD., Hwaseong Si (KR)

(21) Appl. No.: 12/907,413

(22) Filed: Oct. 19, 2010

(30) Foreign Application Priority Data
Apr. 19, 2010 (KR) 10-2010-0035686

(51) Int. Cl. H01L 31/052; F16C 35/02

(52) U.S. Cl. 136/246; 384/428

(57) ABSTRACT

A torque tube supporter and a solar tracker using the same are provided. The torque tube supporter includes a cylindrical bearing supporting a cylindrical torque tube, a bearing cover having a cylindrical middle portion for supporting the bearing, a flange radially protruding from the circumference of the bearing cover, a half journal section having an arcuate upper portion to which the flange is fixed, and a post supporting the half journal section.

### BACKGROUND OF THE INVENTION

1. Field of the Invention

The present invention relates, in general, to a torque tube supporter and a solar tracker using the same, and more particularly to a supporter for supporting a cylindrical torque tube and a solar tracker using the same.

2. Description of the Related Art

Generally, solar trackers are devices that allow a solar panel to track sunlight in relation to the position of the sun such that the horizontal surface of the solar panel is placed perpendicular to the sun in order to improve the efficiency with which electricity is generated.

Recent interest in solar energy has increased and a variety of solar trackers are being proposed. Korean Patent No. 0864215 discloses a solar tracker in which a solar panel is mounted not in a single module frame, but in a module frame using a plurality of crank axes. Korean Patent Laid-open Publication No. 2009-0108261 discloses a solar tracker that ensures that the relative revolving motion of a torque tube to a supporter is smooth while at the same time increasing the coupling force between the supporter and the torque tube. Meanwhile, Korean Patent No. 0886376 discloses a solar tracker which has a stopper at one point in a link connection to prevent distortion of a supporter structure.

However, since the torque tube of the related art has a rectangular section, the torque tube has the problem of when used for a long time running the risk of suffering from distortion and deformation caused by distortion stress generated upon its making revolutions.

Another problem occurs wherein when an angle of the torque tube is controlled by an action of a driver, precise control of the angle is difficult to implement because of the rectangular section of the torque tube.

A further problem occurs wherein the sectional shapes of the torque tube and a bearing supporting the torque tube are different from each other, so that stress in the section of the bearing is unevenly distributed and thus overran excessive load is applied onto the bearing.

### SUMMARY OF THE INVENTION

Accordingly, the present invention has been made keeping in mind the above problems occurring in the related art, and the present invention intends to propose a torque tube supporter capable of improving long-term durability and precisely tracking sunlight, and minimizing overload applied onto structures, and a solar tracker using the same.

There is provided, in order to achieve the above object according to one aspect of the present invention, a torque tube supporter including: a cylindrical bearing supporting a cylindrical torque tube; a bearing cover having a cylindrical middle portion for supporting the bearing; a flange radially protruding from the circumference of the bearing cover; a half journal section having an arcuate upper portion to which the flange is fixed; and a post supporting the half journal section.

In an exemplary embodiment, the half journal section may be composed of a pair of left and right half journals having the same shape, the bearing cover may be composed of a pair of left, right bearing cover parts which are mounted onto the left, right half journals, respectively, and a fastening bolt may be provided to pass through all of the left half journal, the left bearing cover part, the right bearing cover part, and the right half journal.

In an exemplary embodiment, the bearing cover may be provided on a rear end with a bent portion covering the rear end.

According to another aspect of the present invention, there is provided a solar tracker including: a cylindrical torque tube; a first torque tube supporter including a cylindrical bearing supporting the torque tube, a bearing cover having a cylindrical middle portion for supporting the bearing, a flange radially protruding from the circumference of the bearing cover, a half journal section fixed to the flange, and a post supporting the half journal section; a second torque tube supporter having the same shape as the first torque tube supporter and installed in such a way as to be spaced apart from the first torque tube supporter; a first solar panel coupled to one end of a torque tube; a second solar panel coupled to another end of the torque tube; a lever arm having an end integrally formed on a middle portion of the torque tube; a link member hinge-coupled to another end of the lever arm; and a driving section driving the link member.

In an exemplary embodiment, a plurality of pairs of first and second torque tube supporters may be mounted in such a way that they are spaced apart from each other along the longitudinal direction of the link member, and the driving section may be positioned at the middle of the link member.

The present invention provides following effects.

The cylindrical torque tube is retained by the bearing such that distortion stress occurring on the torque tube is uniformly distributed, thereby preventing degradation of long-term durability.

Further, even when the torque tube is subjected to strong winds at the place where the solar tracker is installed, the distortion stress resulting therefrom is uniformly distributed over the whole sectional area, so that the torque tube becomes resistant to fatigue fracture.

Further, since the coupling structure of the bearing, the bearing cover, and the half journal for supporting the cylindrical torque tube is simple, the torque tube supporter can be quickly mounted with ease at the scene.

Further, since the bearing is covered on the whole circumference with the first and second bearing covers in a close-contact manner, even upon revolution, the stress distribution over the bearing becomes constant, thereby reducing the risk of breakage.

Further, since the upper portion of the half journal is of an arcuate shape, the half journal does not interfere with the revolution of the bearing, thereby increasing the efficiency of using the parts.

Further, since the rear portion of the bearing cover has a bent portion extending opposite the radial direction, the bearing is prevented from deviating from the bearing cover, keeping the concentricity of the torque tube constant.

Furthermore, the half journal and the bearing cover are fastened together from the opposite posts by a single fastening bolt, keeping the concentricity of the torque tube constant.

### BRIEF DESCRIPTION OF THE DRAWINGS

The above and other objects, features and advantages of the present invention will be more clearly understood from the following detailed description when taken in conjunction with the accompanying drawings, in which:

FIG. 1 is an exploded perspective view showing a torque tube supporter according to an embodiment of the invention;

FIG. 2 is a perspective view showing the assembled state of the torque tube supporter;

FIG. 3 is a front view of FIG. 2;

FIG. 4 is a side view of FIG. 2;

FIG. 5 is a front view showing a solar tracker according to an embodiment of the invention;

FIG. 6 is a side view showing the assembly of a lever arm and a link member according to an embodiment; and

FIG. 7 is a view showing the installed state of the solar tracker according to an embodiment.

### DETAILED DESCRIPTION OF THE INVENTION

Reference will now be made in greater detail to a preferred embodiment of the invention, an example of which is illustrated in the accompanying drawings. Wherever possible, the same reference numerals will be used throughout the drawings and the description to refer to the same or like parts.

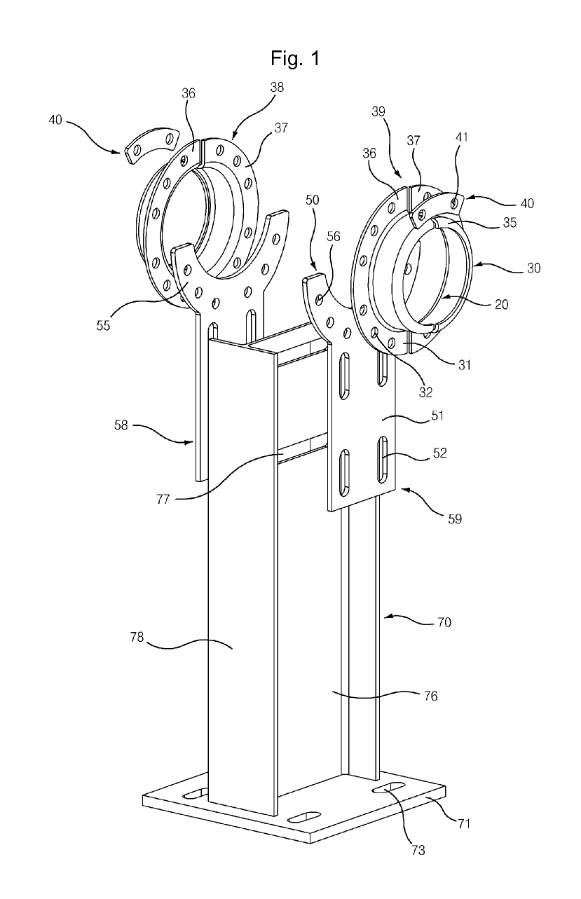

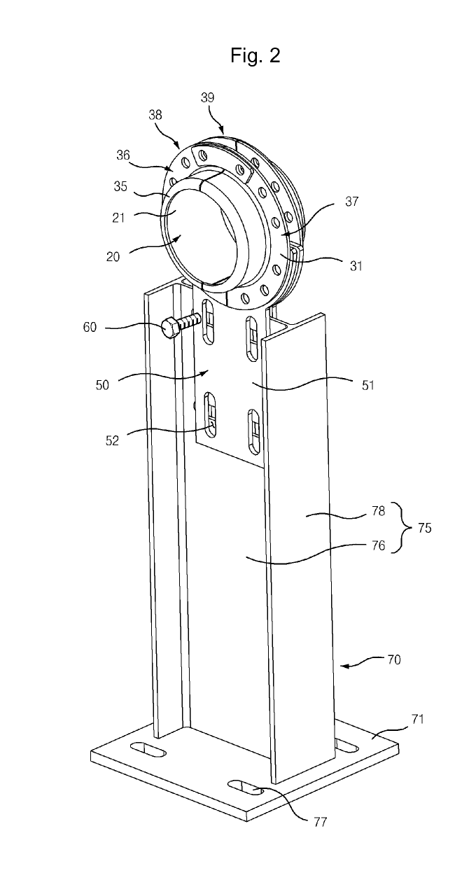

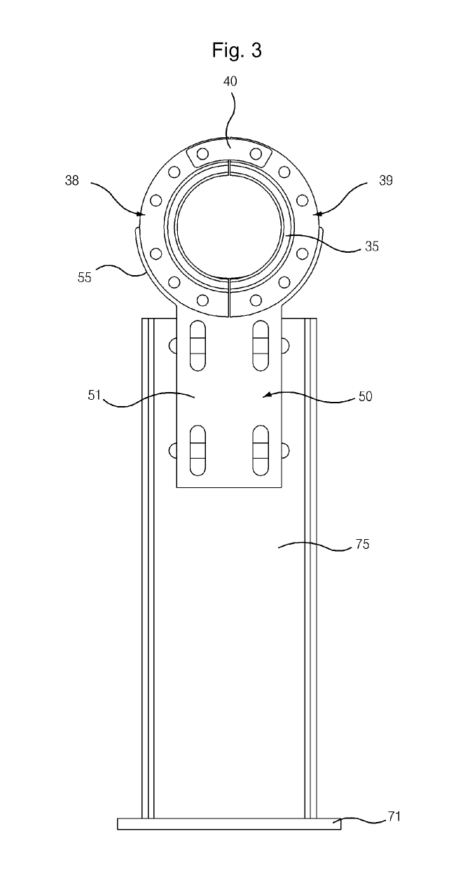

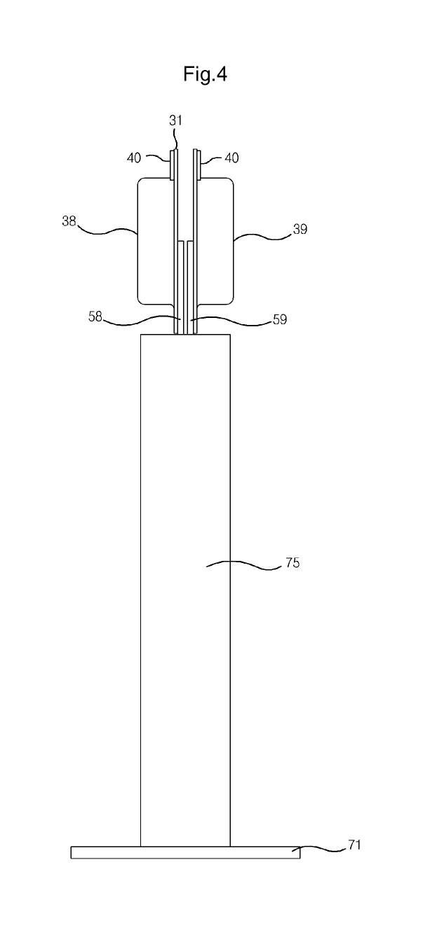

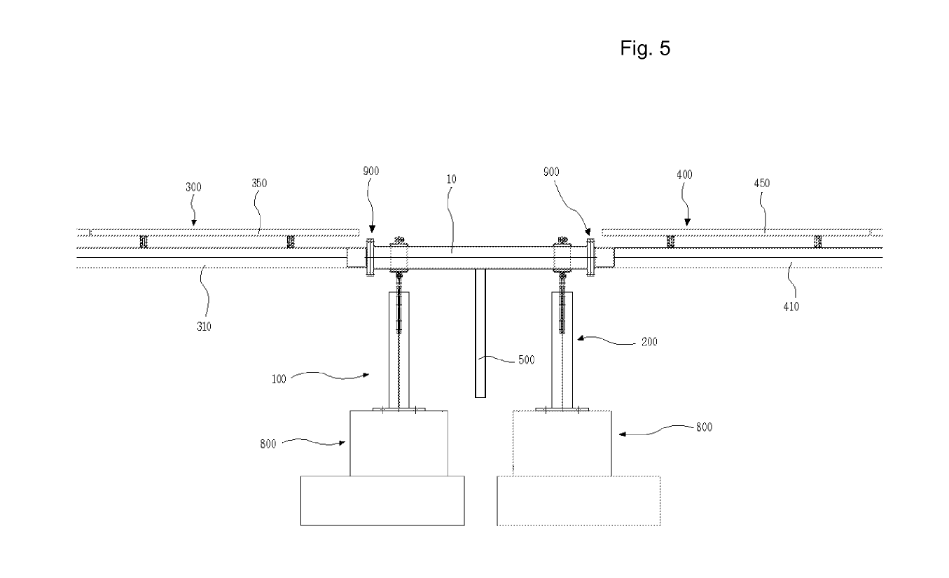

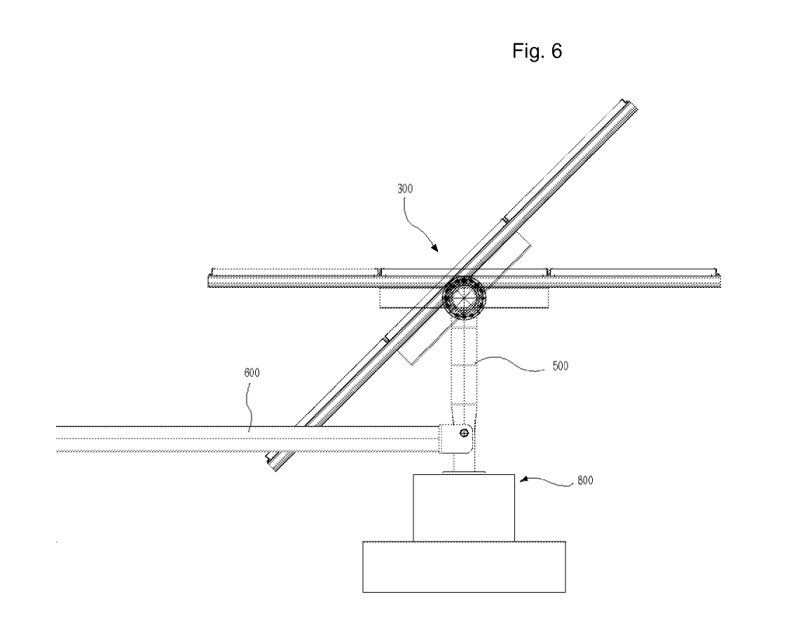

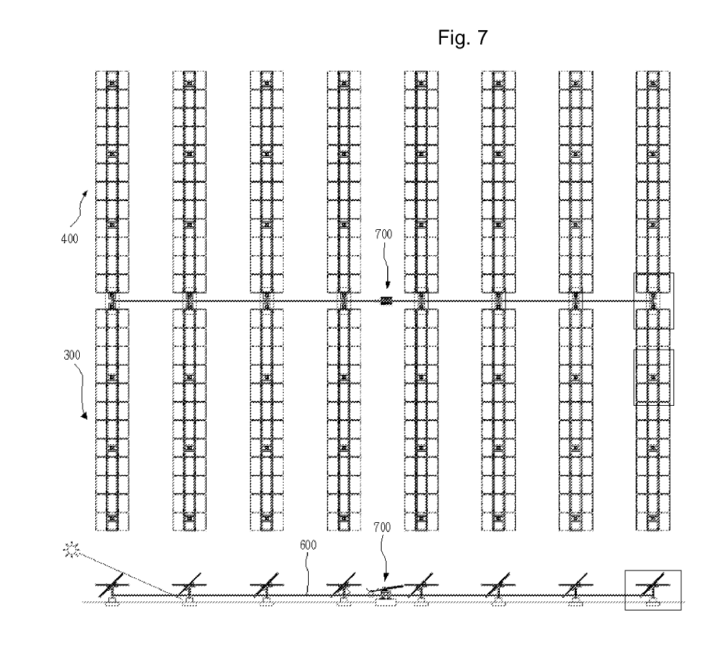

FIG. 1 is an exploded perspective view showing a torque tube supporter according to an embodiment of the invention, FIG. 2 is a perspective view showing the assembled state of the torque tube supporter, FIG. 3 is a front view of FIG. 2, FIG. 4 is a side view of FIG. 2, FIG. 5 is a front view showing a solar tracker according to an embodiment of the invention, FIG. 6 is a side view showing the assembly of a lever arm and a link member according to an embodiment, and FIG. 7 is a view showing the installed state of the solar tracker according to an embodiment.

The torque tube supporter according to an embodiment will now be described with reference to FIGS. 1 to 4.

The torque tube supporter includes a bearing 20, a bearing cover 30, a half journal section 50, and a post 70.

The bearing 20 is in a cylindrical shape designed to support a cylindrical torque tube 10 (see FIG. 5). The bearing 20 is made of polyethylene, consists of a first bearing part 21 and a second bearing part 25, which are evenly halved from the bearing, and is mounted inside the bearing cover 30.

The diameter of the combined bearing parts 21 and 25 is larger than that of the torque tube 10 such that the outer circumference of the cylindrical torque tube 10 is closely surrounded by inner circumferences of the first, second bearing parts 21 and 22. Thus, the bearing parts firmly support the torque tube 10.

The bearing cover 30 is provided on the outer circumference with a flange 31 which radially extends in a certain width along the circumferential direction. The flange 31 is provided with a plurality of fixing holes 32.

The bearing cover 30 is provided on the rear portion thereof with a bent portion 35 which is bent in a circumferentially inner direction from the rear portion. The bent portion 35 surrounds the rear portion of the bearing 20 in order to prevent the bearing 20 from coming out of the bearing cover 30.

The bearing cover 30 consists of first and second bearing cover parts 36 and 37 which are evenly halved from the bearing cover. The first and second bearing cover parts 36 and 37 are of the same shape, so that upon mounting on location, either one bearing cover part can replace the other part.

The first and second bearing cover parts 36 and 37 have joining surfaces on upper and lower ends, so that they can be easily mounted on the bearing such that the inner circumferential surfaces come into close contact with the outer circumferential surface of the bearing 20.

The joining surfaces formed on the upper ends of the first and second bearing cover parts 36 and 37 are fastened to each other by bolting a cover joint 40 to the cover parts near the adjoining surfaces using bolts (not shown). The cover joint 40 connects the first and second bearing cover parts 36 and 37 to each other and the coupling force depends upon the stiffness of the cover joint 40, so that the cover joint 40 may have only two bolting holes 41.

Since the lower portions of the first and second bearing cover parts 36 and 37 respectively are fixed onto the half journal section 50, the joining surfaces at the lower portions of the first and second bearing cover parts 36 and 37 may not be coupled by a separate cover joint 40.

A flange 35 of the bearing cover 30 is fixed to the half journal section 50.

The half journal section 50 includes a body 51 fastened to the post 70, and an upper section 55 formed on an upper portion of the body 51. The body 51 is provided with a plurality of bolt holes 52 to make the connection with the post 70. The upper section 55 is in an arcuate shape and has a plurality of fixing holes 56.

The arcuate upper section of the half journal section 50 enables the bearing cover 30 to be firmly fixed onto the half journal section 50 without interfering with revolution of the torque tube.

The post 70 includes a base plate 71 fixed on the foundation 800, and a support plate 75 extending upwards from the base plate 71. The base plate 71 has a plurality of fixing holes 73 to be fixed to the foundation 800.

The support plate 75 includes an intermediate part 76 and two side parts 78 formed on opposite sides of the intermediate part 76. The support plate 75 may be a commercial H-section steel product. The intermediate part 76 has a plurality of fixing holes 77 for fixation with the half journal 50.

The intermediate part 76 of the support plate 75 is formed perpendicular to the torque tube 10, so that even when a driving section 700 applies operational load to a lever arm 500, the support plate 75 can firmly support the torque tube 10 because the high strength support plate 75 is able to resist the bending moment.

The half journal section 50 consists of left and right half journals 58 and 59 which are of the same shape. The left and right half journals 58 and 59 are fastened to opposite sides of the support plate 75 of the post 70. The left and right bearing cover parts 38 and 39 are respectively fastened to the left and right half journals 58 and 59.

Thus, the left bearing cover part 38, the left half journal 58, the right half journal 59, and the right bearing cover part 39 are fastened together in order as named by connecting a fastening bolt 60 through the fixing holes 32, 56, 56, and 32. There are a multiple of fastening bolts 60 provided.

The bearings 20 are mounted surrounded by the bent portions 35 of the left and right bearing cover parts 38 and 39. Here, the bearing passes through and is supported by the left bearing cover part 38, the left half journal 58, the intermediate part 76, the right half journal 59, and the right bearing cover part 39.

Hereinafter, the solar tracker equipped with the torque tube supporter according to an embodiment will be described in detail with reference to FIG. 5.

The cylindrical torque tube 10 is mounted on opposite sides with a first torque tube supporter 100 and a second torque tube supporter 200 such that the torque tube 10 can be supported in a manner that revolves freely.

The first torque tube supporter 100 includes a cylindrical bearing 20 supporting the cylindrical torque tube 10, a bearing cover 30 having a cylindrical middle portion for supporting the bearing 20, a flange 31 radially protruding from the circumference of the bearing cover 30, a half journal section 50 fixed to the flange 31, and a post 70 supporting the half journal section 50. The second torque tube supporter 200 is of the same shape as the first torque tube supporter 100, and is mounted a certain distance away from the first torque tube supporter 100.

The first and second torque tube supporters 100 and 200 are firmly fixed to the foundation 800. The foundation may be, but is not limited to, concrete structures, or otherwise may be a rock bed, aggregate, the ground, or the like.

Coupling sections 900 are provided on opposite sides of the torque tube 10. The coupling section 900 is a section for connecting the cylindrical torque tube 10 with a rectangular frame.

On the left of the torque tube 10, a first solar panel 300 is mounted, which includes a first frame 310 in rectangular section and a first solar condenser 350.

The first solar condenser 350 is supported by the first frame 310, and the horizontal surface is perpendicular to sunlight. The first solar condenser 350 is composed of a plurality of solar cells.

On the right of the torque tube 10, a second solar panel 400 is mounted, which includes a second frame 410 in rectangular section and a second solar condenser 450. The second solar condenser 450 is supported by the second frame 410, and the horizontal surface is perpendicular to the sunlight. Like the first solar condenser, the second solar condenser 450 is composed of a plurality of solar cells.

A lever arm 500 is welded to the middle portion of the torque tube 10.

Referring to FIG. 6, an end of the lever arm 500 is integrally coupled to the torque tube 10, and another end of the lever arm is hinge-coupled to a link member 600. FIG. 6 illustrates an end side of the solar tracker once it is installed. In FIG. 6, while only one link member 600 is coupled to the lever arm 500, two link members 600 are hinge-coupled to the other end of the lever arm 500 on the side that is not the end side.

Referring to FIG. 7, in the solar tracker, a driving section 700 is positioned at the middle of the solar tracker in the horizontal direction. That is, the driving section 700 is mounted at the middle of the whole link member 600. Thus, as compared to the case where the driving section 700 is mounted on an end side in the horizontal arrangement, the distortion stress applied to the torque tube 10 can be minimized. Since the altitude and location of the sun depending on year, date, and time at the place where the solar tracker is installed are previously stored in the driving section 700, the link member 600 accordingly operates to control the horizontal surface of the solar panel to be perpendicular to the sunlight.

When the torque tube 10 revolves while being supported by the torque tube supporter while using the angle of forward and backward actions of the lever arm 500, the revolving force enables the first and second solar panels 300 and 400, coupled on opposite sides, to revolve. The first and second solar panels 300 and 400 are supported by the first and second frames 310 and 410. Here, when revolving the torque tube 10, the first and second frames, which support much of the weight of the torque tube, also have to revolve, so that excessive distortion stress is generated on the torque tube 10. According to the present invention, the cylindrical torque tube 10 is supported by the bearing 20 so that the distortion stress occurring on the torque tube 10 is evenly distributed, thereby preventing the durability from being reduced even after having been used for a long time.

Further, even when the torque tube 10 is subject to strong winds at the place where the solar tracker is installed, the distortion stress is uniformly distributed over the whole sectional area, so that the torque tube 10 becomes resistant to fatigue fracture.

Further, since the coupling structure of the bearing 20, the bearing cover 30, and the half journal section 50 for supporting the cylindrical torque tube 10 is simple, the torque tube supporter can be quickly mounted with ease on location.

Further, since the bearing 20 is covered over the entirety of its circumference with the first and second bearing cover parts 36 and 37 in a close-contact manner, upon revolution of the bearing 20, the risk of breakage is reduced.

Further, since the upper portion of the half journal section 50 is of an arcuate shape, the half journal section does not interfere with the revolution of the bearing 20, thereby increasing the efficiency of using the parts.

Further, since the rear portion of the bearing cover 30 has the bent portion 35 extending opposite the radial direction, the bearing 20 is prevented from coming out of the bearing cover 30, keeping the concentricity of the torque tube 10 constant.

Furthermore, the half journal section 50 and the bearing cover 30 are fastened together from the opposite portions of the post by a single fastening bolt 60, keeping the concentricity of the torque tube 10 constant.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A torque tube supporter comprising:
a cylindrical bearing supporting a cylindrical torque tube;
a bearing cover having a cylindrical middle portion for supporting the bearing;
a flange radially protruding from the circumference of the bearing cover;
a half journal section having an arcuate upper portion to which the flange is fixed; and
a post supporting the half journal section.

2. The torque tube supporter according to claim 1, wherein the half journal section is composed of a pair of left, right half journals having the same shape, wherein the bearing cover is composed of a pair of left, right bearing cover parts which are mounted onto the left, right half journals, respectively, and wherein a fastening bolt is provided to pass through all of the left half journal, the left bearing cover part, the right bearing cover part, and the right half journal.

3. The torque tube supporter according to claim 1, wherein the bearing cover is provided on a rear end with a bent portion covering the rear end.

4. A solar tracker comprising:
a cylindrical torque tube;
a first torque tube supporter including a cylindrical bearing supporting the torque tube, a bearing cover having a cylindrical middle portion for supporting the bearing, a flange radially protruding from the circumference of the bearing cover, a half journal section fixed to the flange, and a post supporting the half journal section;
a second torque tube supporter having the same shape as the first torque tube supporter and installed in such a way as to be spaced apart from the first torque tube supporter;
a first solar panel coupled to one end of a torque tube;
a second solar panel coupled to another end of the torque tube;
a lever arm having an end integrally formed on a middle portion of the torque tube;
a link member hinge-coupled to another end of the lever arm; and
a driving section driving the link member.

5. The solar tracker according to claim 4, wherein a multiple of pairs of the first and second torque tube supporters are mounted so as to be spaced apart from each other along the longitudinal direction of the link member, and wherein the driving section is positioned at the middle of the link member.
